(19) United States
(12) Patent Application Publication
(10) Pub. No.: US 2014/0321009 A1
(43) Pub. Date: Oct. 30, 2014

(54) ESD PROTECTION MATERIAL AND ESD PROTECTION DEVICE USING THE SAME

(71) Applicant: SAMSUNG ELECTRO-MECHANICS CO., LTD., Suwon-Si (KR)

(72) Inventors: Jeong Bok KWAK, Suwon-Si (KR); Jun Hee BAE, Suwon-Si (KR); Sang Moon LEE, Suwon-Si (KR); Young Seuck YOO, Suwon-Si (KR)

(73) Assignee: SAMSUNG ELECTRO-MECHANICS CO., LTD., Suwon-Si (KR)

(21) Appl. No.: 14/260,023

(22) Filed: Apr. 23, 2014

(30) Foreign Application Priority Data
Apr. 26, 2013 (KR) 10-2013-0046636

(51) Int. Cl. H05K 9/00

(52) U.S. Cl. CPC H05K 9/0079; H05K 9/0067
USPC 361/56; 252/512; 252/513; 252/514; 252/511

(57) ABSTRACT

Disclosed herein is an electrostatic discharge protection material having more stable operation characteristic by mixing and dispersing inorganic particles and metal particles in a resin matrix and an electrostatic discharge protection device using the same.

### CROSS REFERENCE(S) TO RELATED APPLICATIONS

This application claims the benefit under 35 U.S.C. Section 119 of Korean Patent Application Serial No. 10-2013-0046636, entitled “ESD Protection Material and ESD Protection Device using the Same” filed on Apr. 26, 2013, which is hereby incorporated by reference in its entirety into this application.

### BACKGROUND OF THE INVENTION

1. Technical Field

The present invention relates to an electrostatic discharge (ESD) protection device, and more particularly, to a particle structure of an ESD protection material included in the ESD protection device.

2. Description of the Related Art

Recently, implementation for miniaturization and high performance of an electronic device such as a portable telephone, and implementation for high speed (an implementation for a high frequency above 1 GHz) of a transmitting speed represented by a universal serial bus 2.0 (USB 2.0), an USB 3.0, a S-ATA2, a HDMI, or the like has rapidly progressed. However, as a reaction thereof, withstand voltage of the electronic device has gradually low. Therefore, a protection of the electronic device from electrostatic pulse generated when a human body and a terminal of the electronic device contact with each other is gradually emerging as a main issue.

In order to protect the electronic device from the electrostatic pulse described above, an electrostatic discharge protection device (hereinafter, called an ESD protection device) is generally connected between a line to which electrostatic is input and a ground.

Referring to the following Patent Document, an ESD protection device according to the related art has an electrostatic discharge protection material (hereinafter, called an ESD protection material) filled between a pair of electrodes facing each other, where the ESD protection material has a structure in which various metal particles are dispersed into an insulating resin matrix.

As a result, in a normal operation state without the electrostatic pulse, since a resistance value between the pair of electrodes has infinite magnitude, current does not flow through the pair of electrodes and a normal input signal flows toward the electronic device. However, when over-voltage caused by the electrostatic is applied, a conductive path is generated between the metal particles, such that an electronic tunneling phenomenon that the current is conducted between the pair of electrodes occurs. Therefore, the current caused by the over-voltage is bypassed to the ESD protection device to exit to the ground, thereby making it possible to protect the electronic device from the over-voltage.

### RELATED ART DOCUMENT

### Patent Document

(Patent Document 1) Japanese Patent Laid-Open Publication No. 2010-165660

### SUMMARY OF THE INVENTION

However, since the metal particles described in Patent Document has an island form, an interval between the metal particles is randomly formed. As a result, a problem has generated that a desired ESD effect may not be obtained in a region in which the interval between the metal particles is too far, and the current flows at desired voltage or less in a region in which the interval between the metal particles is too close.

An object of the present invention is to provide an ESD protection material solving the problem by arranging metal particles at a constant interval and an ESD protection device using the same.

According to an exemplary embodiment of the present invention, there is provided an electrostatic discharge protection material, including: a resin matrix; and inorganic particles and metal particles dispersed and mixed in the resin matrix.

The metal particles may be positioned between the inorganic particles.

The metal particle may have a diameter smaller than that of the inorganic particle.

The metal particle may be positioned between the inorganic particles and has a diameter smaller than that of the inorganic particle.

The inorganic particle and the metal particle may have a diameter ratio of 1.3 to 0.15.

The inorganic particle may be made of at least one substance selected from a group consisting of Al₂O₃, SiO₂, TiO₂, ZnO, In₂O₃, NiO, CoO, SnO₂, ZrO₂, CuO, MgO, AlN, BN, and SiC, or a compound thereof.

The metal particle may be made of at least one metal selected from a group consisting of C, Ni, Cu, Au, Ti, Cr, Ag, Pd, and Pt, or a metal compound thereof.

The inorganic particle may be made of two or more kinds of particles having different diameters.

The metal particle may be made of two or more kinds of particles having different diameters.

The inorganic particle and the metal particle may be made of two or more kinds of particles having different diameters, respectively.

According to another exemplary embodiment of the present invention, there is provided an electrostatic discharge protection material, including: a resin matrix; and first inorganic particles, second inorganic particles, and first metal particles dispersed and mixed in the resin matrix, wherein the first metal particle may have a diameter smaller than that of the first inorganic particle and the second inorganic particle may have a diameter smaller than that of the first metal particle.

The first inorganic particle, the first metal particle, and the second inorganic particle may have a diameter ratio of 1.3 to 0.15 to 0.03.

Second metal particles having a diameter smaller than that of the second inorganic particle may be dispersed and mixed in the resin matrix.

The first inorganic particle, the first metal particle, the second inorganic particle, and the second metal particle may have a diameter ratio of 1.3 to 0.15 to 0.03 to 0.004.

According to another exemplary embodiment of the present invention, there is provided an electrostatic discharge protection device, including: an insulating substrate; a pair of electrodes spaced apart from each other and disposed to face each other; and a function layer provided on the insulating substrate so as to cover a gap between the pair of electrodes, wherein the function layer may be configured of any one of the electrostatic discharge protection materials described above.

### BRIEF DESCRIPTION OF THE DRAWINGS

FIG. 1 is a cross-sectional view of an ESD protection device according to an exemplary embodiment of the present invention;

FIG. 2 is a plan view of the ESD protection device according to the exemplary embodiment of the present invention;

FIGS. 3 to 6 are enlarged views of one region of an ESD protection material included in the exemplary embodiment of the present invention; and

FIGS. 7 and 8 are enlarged views of one region of an ESD protection material according to another exemplary embodiment of the present invention.

### DESCRIPTION OF THE PREFERRED EMBODIMENTS

Various advantages and features of the present invention and technologies accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art.

Terms used in the present specification are for explaining exemplary embodiments rather than limiting the present invention. Unless explicitly described to the contrary, a singular form includes a plural form in the present specification. Components, steps, operations, and/or elements stated herein does not exclude the existence or addition of one or more other components, steps, operations and/or elements.

Hereinafter, a configuration and an acting effect of exemplary embodiments of the present invention will be described in more detail with reference to the accompanying drawings.

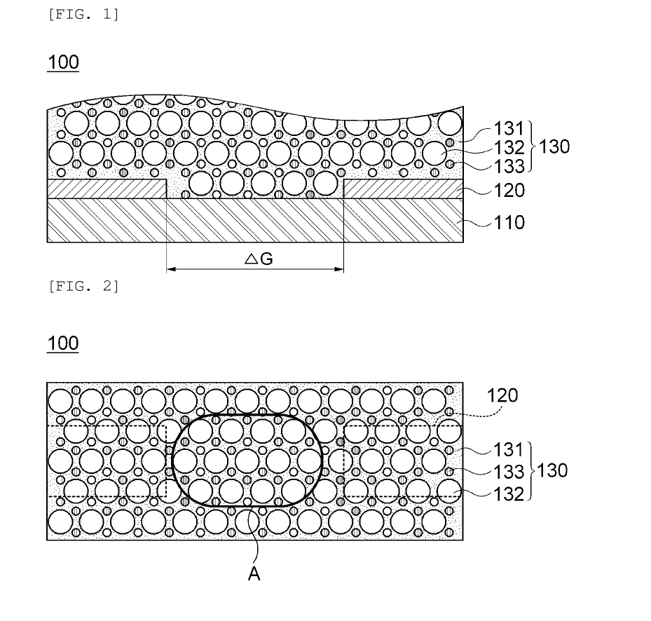

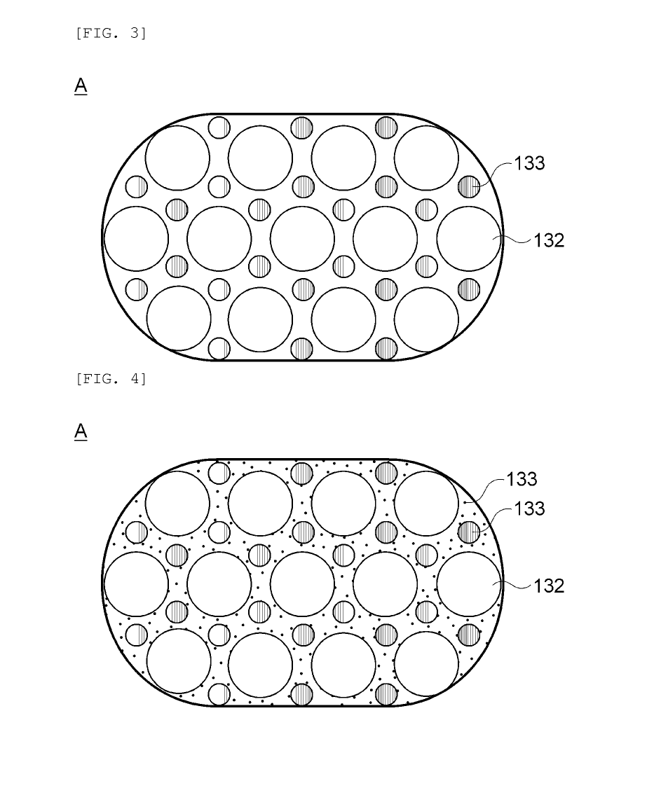

FIG. 1 is a cross-sectional view of an ESD protection device according to an exemplary embodiment of the present invention and FIG. 2 is a plan view of the ESD protection device according to the exemplary embodiment of the present invention. Additionally, components shown in the accompanying drawings are not necessarily shown to scale. For example, sizes of some components shown in the accompanying drawings may be exaggerated as compared with other components in order to assist in the understanding of the exemplary embodiments of the present invention and this is applied to FIGS. 1 to 8 proposed below.

Referring to FIG. 1, an ESD protection device 100 according to an exemplary embodiment of the present invention may include an insulating substrate 110, a pair of electrodes 120 formed on any one surface of the insulating substrate 110, and a function layer 130 provided at a surface of the insulating substrate 110 so as to cover a gap between the pair of electrodes 120.

The insulating substrate 110 may be any substrate along as it may support the pair of electrodes 120 and the function layer 130. In addition, the insulating substrate 110 has no limitation in a size or a shape thereof and may be variously manufactured according to an electronic device to which the ESD protection device 100 according to the exemplary embodiment of the present invention is applied.

The insulating substrate 110 may be any substrate in which the surface having the pair of electrodes 120 and the function layer 130 provided thereon has insulation. Therefore, the insulating substrate 110 may have a concept including the substrate in which an insulating film is formed on a portion or an entire surface on the substrate, other than the substrate made of an insulating material.

Specifically, the insulating substrate 110 may be a ceramic substrate or a single crystal substrate made of alumina, silica, magnesia, aluminum nitride, forsterite, or the like. In addition, the insulating substrate 110 in which the insulating film made of alumina, silica, magnesia, aluminum nitride, forsterite, or the like is formed on a surface of the ceramic substrate or the single crystal substrate may be used.

The pair of electrodes 120 are spaced apart from each other and disposed on any one surface of the insulating substrate 110 to face each other, where the pair of electrodes 120 according to the exemplary embodiment of the present invention have a gap distance (ΔG) at a center position of the insulating substrate 110 and disposed to face each other. Here, the gap distance (ΔG) may be appropriately set in consideration of desired discharge characteristic and may be typically about 1 to 50 μm.

A material configuring the pair of electrodes 120 may be at least one metal selected from C, Ni, Al, Fe, Cu, Ti, Cr, Au, Ag, Pd, and Pt, for example, or a metallic compound thereof, but is not particularly limited thereto. In addition, according to the exemplary embodiment of the present invention, the pair of electrodes 120 are formed in a rectangular shape and may be formed in a comb shape or a saw tooth shape, for example, but is not particularly limited.

The pair of electrodes 120 may have the function layer 130 made of the ESD protection material disposed therebetween. The function layer 130 may be formed by performing a screen print or the like using the ESD protection material having paste form on one surface of the insulating substrate 110 including the space between the pair of electrodes 120.

A size, a shape, or the like of the function layer 130 is not particularly limited as long as the function layer 130 is designed so as to secure initial discharge between the pair of electrodes 120 through the function layer 130 when the over-voltage is applied thereto. In addition, a thickness of the function layer 130 is also not particularly limited, but may be formed as a thin film having the thickness of about 10 nm to 10 μm in view of implementing miniaturization and high performance of the electronic device using the ESD protection device according to the exemplary embodiment of the present invention.

The ESD protection material, which is a material configuring the function layer 130 has characteristic that allows inorganic particles 132 and metal particles 133 to be dispersed and mixed in an insulating resin matrix 131. In this case, the metal particles 133 need to be appropriately contained according to required clamping voltage, that is, critical voltage generating an electron tunneling phenomenon and the inorganic particles 132 and the metal particles 133 may have a weight ratio of 7 to 3.

The metal particles 133 may be made of at least one metal selected from a group consisting of C, Ni, Cu, Au, Ti, Cr, Ag, Pd, and Pt, or a metallic compound thereof and the inorganic particle 132 may be made of at least one substance selected from a group consisting of Al₂O₃, SiO₂, TiO₂, ZnO, In₂O₃, NiO, CoO, SnO₂, ZrO₂, CuO, MgO, AlN, BN, and SiC, or a compound thereof.

A specific example of a resin material used as the matrix of the ESD protection material may include a polymer material such as epoxy resin, phenol resin, urethane resin, silicon resin, or polyimide resin. One kind of them may be used alone and two or more kinds of them may be used in combination.

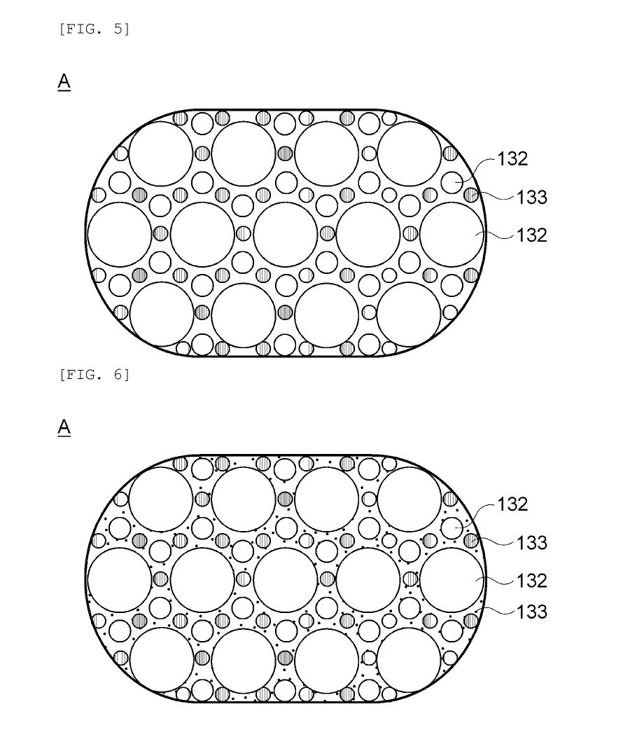

FIG. 3 is an enlarged view of one region (an A region of FIG. 2) of the ESD protection material. Referring to FIG. 3, a diameter of the metal particle 133 may be formed to be smaller than that of the inorganic particle 132.

More specifically, the inorganic particle 132 and the metal particle 133 may have a diameter ratio of 1.3 to 0.15. Therefore, as shown in FIG. 3, the metal particles 133 are disposed between the inorganic particles 132, such that possibility of the metal particles disposed at a constant interval is increased.

As a result, a problem caused by an interval between the metal particles 133 may be solved, and the inorganic particles 132 also serve as a preform in the resin matrix 131, thereby making it possible to prevent the function layer 130 from being destroyed even when strong current flows during a short time.

Meanwhile, in order to increase packing density of the metal particles 133, the metal particles 133 may be configured of two or more kinds of particles having different diameters, as shown in FIG. 4. In this case, fine particles of the metal particles 133 may be evenly dispersed in the resin matrix 131, thereby making it possible to increase electrostatic withstand voltage characteristic.

In addition, in order to more densely dispose the interval between the metal particles 133, the inorganic particles 132 may be configured of two or more kinds of particles having different diameters, as shown in FIG. 5. In this case, the fine particles of the inorganic particles 132 are disposed between coarse particles of the inorganic particles 132 and the metal particles 133 are disposed between the fine particles of the inorganic particles 132, such that the interval between the metal particles 133 may become closer, as shown in FIG. 5.

In addition, the packing density of the metal particles 133 may be increased by configuring the metal particles 133 using two or more kinds of particles having different diameters, as shown in FIG. 6.

Hereinafter, an ESD protection material according to another exemplary embodiment of the present invention will be described.

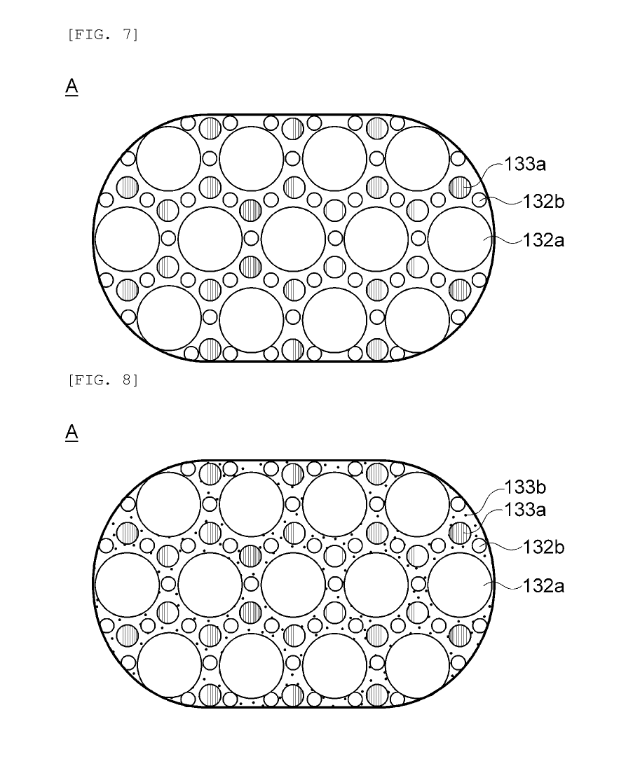

FIG. 7 is an enlarged view of one portion of the ESD protection material according to another exemplary embodiment of the present invention, where the ESD protection material according to another exemplary embodiment of the present invention may include first inorganic particles 132a, second inorganic particles 132b, and first metal particles 133a dispersed and mixed in the resin matrix.

Here, the first metal particle 133a has a diameter smaller than that of the first inorganic particle 132a and the second inorganic particle 132b has a diameter smaller than that of the first metal particle 133a.

More specifically, the first inorganic particle 132a, the first metal particle 133a, and the second inorganic particle 132b may have a diameter ratio of 1.3 to 0.15 to 0.03. Therefore, the first metal particles 133a may be positioned between the first inorganic particles 132a and the second inorganic particles 132b may be positioned between the first metal particles 133a.

In FIG. 3 as described above, although the metal particles 133 are disposed at the constant interval, due to a diameter difference between the inorganic particle 132 and the metal particle 133, if the diameter of the metal particle 133 is too small, the metal particles 133 are aggregated in empty spaces between the inorganic particles 132. However, as shown in FIG. 7, the second inorganic particle 132b having the diameter smaller than that of the first metal particle 133a is disposed between the first metal particles 133a, thereby making it possible to suppress a aggregation phenomenon of the first metal particles 133a. As a result, the first metal particles 133a may be evenly dispersed in the resin matrix 131.

In addition, as shown in FIG. 8, the packing density of the metal particles 133 may be increased by mixing second metal particles 133b having a diameter smaller than that of the second inorganic particle 132b. In this case, the first inorganic particle 132a, the first metal particle 133a, the second inorganic particle 132b, and the second metal particle 133b may have a diameter ratio of 1.3 to 0.15 to 0.03 to 0.004.

According to the exemplary embodiment of the present invention, the metal particles are arranged at the constant interval in the resin matrix, thereby making it possible to secure the stable operation of the ESD protection device.

In addition, the above mentioned object may be achieved in a simplified method, that is, a mix of the inorganic particles and the metal particles, such that the product may be easily implemented.

In addition, the inorganic powder included in the resin matrix serves as the preform, thereby making it possible to increase the reliability of the product.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

1. An electrostatic discharge protection material, comprising:
a resin matrix; and
inorganic particles and metal particles dispersed and mixed in the resin matrix.

2. The electrostatic discharge protection material according to claim 1, wherein the metal particles are positioned between the inorganic particles.

3. The electrostatic discharge protection material according to claim 1, wherein the metal particle has a diameter smaller than that of the inorganic particle.

4. The electrostatic discharge protection material according to claim 1, wherein the metal particle is positioned between the inorganic particles and has a diameter smaller than that of the inorganic particle.

5. The electrostatic discharge protection material according to claim 1, wherein the inorganic particle and the metal particle has a diameter ratio of 1.3 to 0.15.

6. The electrostatic discharge protection material according to claim 1, wherein the inorganic particle is made of at least one substance selected from a group consisting of Al₂O₃, SiO₂, TiO₂, ZnO, In₂O₃, NiO, CoO, SnO₂, ZrO₂, CuO, MgO, AlN, BN, and SiC, or a compound thereof.

7. The electrostatic discharge protection material according to claim 1, wherein the metal particle is made of at least one metal selected from a group consisting of C, Ni Cu, Au, Ti, Cr, Ag, Pd, and Pt, or a metal compound thereof.

8. The electrostatic discharge protection material according to claim 1, wherein the inorganic particle is made of two or more kinds of particles having different diameters.

9. The electrostatic discharge protection material according to claim 1, wherein the metal particle is made of two or more kinds of particles having different diameters.

10. The electrostatic discharge protection material according to claim 1, wherein the inorganic particle and the metal particle are made of two or more kinds of particles having different diameters, respectively.

11. An electrostatic discharge protection material, comprising:
a resin matrix; and
first inorganic particles, second inorganic particles, and first metal particles dispersed and mixed in the resin matrix,
wherein the first metal particle has a diameter smaller than that of the first inorganic particle and the second inorganic particle has a diameter smaller than that of the first metal particle.

12. The electrostatic discharge protection material according to claim 11, wherein the first inorganic particle, the first metal particle, and the second inorganic particle have a diameter ratio of 1.3 to 0.15 to 0.03.

13. The electrostatic discharge protection material according to claim 11, wherein second metal particles having a diameter smaller than that of the second inorganic particle are dispersed and mixed in the resin matrix.

14. The electrostatic discharge protection material according to claim 13, wherein the first inorganic particle, the first metal particle, the second inorganic particle, and the second metal particle have a diameter ratio of 1.3 to 0.15 to 0.03 to 0.004.

15. An electrostatic discharge protection device, comprising:
an insulating substrate;
a pair of electrodes spaced apart from each other and disposed to face each other; and
a function layer provided on the insulating substrate so as to cover a gap between the pair of electrodes,
wherein the function layer is configured of the electrostatic discharge protection material according to claim 1.
